(19) United States
(12) Patent Application Publication
(10) Pub. No.: US 2025/0113427 A1
(43) Pub. Date: Apr. 3, 2025

(54) EUV RADIATION GENERATION FOLLOWING LASER BEAM ROTATION

(71) Applicant: TRUMPF Lasersystems for Semiconductor Manufacturing GmbH, Ditzingen (DE)

(72) Inventors: Stefan Piehler, Stuttgart (DE); Boris Regaard, Stuttgart (DE)

(21) Appl. No.: 18/961,599

(22) Filed: Nov. 27, 2024

Related U.S. Application Data
(63) Continuation of application No. PCT/EP2023/064125, filed on May 25, 2023.

(30) Foreign Application Priority Data
May 30, 2022 (DE) 10 2022 205 360.5

(51) Int. Cl. H05G 2/00

(52) U.S. Cl. CPC H05G 2/0086

(57) ABSTRACT

A device for generating extreme ultraviolet (EUV) radiation includes an optical beam-forming arrangement with a focusing unit for forming a laser beam, and a target material configured to be irradiated with the laser beam to emit EUV radiation. The beam-forming arrangement includes a beam rotator for image field rotation of the laser beam.

### CROSS REFERENCE TO RELATED APPLICATIONS

This application is a continuation of International Application No. PCT/EP2023/064125 (WO 2023/232651 A1), filed on May 25, 2023, and claims benefit to German Patent Application No. DE 10 2022 205 360.5, filed on May 30, 2022. The aforementioned applications are hereby incorporated by reference herein.

### FIELD

Embodiments of the present invention relate to a device for generating EUV radiation. Embodiments of the present invention further relate to a method for generating EUV radiation using such a device.

### BACKGROUND

The generic device and the generic method are known to the applicant, but they have not necessarily become public knowledge.

In this regard, it is known to the applicant to use an optical beam-forming arrangement with a focusing unit in which a laser beam is focused onto a target material. The focusing unit has optical elements which are arranged, in particular, in a vacuum chamber and which are suitable for focusing the laser beam onto the target material. The focal position of the laser beam must be adjustable in order, for example, to adjust the focal position to the position of the target material and thus achieve the maximum possible EUV power, among other reasons. Here, the lateral focal position of the laser beam is adjusted outside of the beam-forming arrangement by tilting and/or shifting a laser beam entering the beam-forming arrangement. The focal position in the beam direction of the laser beam is also controlled outside of the beam-forming arrangement by adjusting the divergence of the laser beam. The beam-forming arrangement has one or more optical elements by means of which the laser beam is deflected and/or formed, i.e., a laser beam entering the beam-forming arrangement and a laser beam focusing on the target material are not collinear to one another. Such a beam deflection by means of one or more optical elements creates an image field rotation, i.e., for example, a horizontal tilt of the input beam entering the beam-forming arrangement does not lead to a horizontal shift of the focal position, but rather, for example, to a shift along an axis rotated relative to the horizontal. In order to be able to adjust the focal position, the input and output behavior of the laser beam and thus the image field rotation must be known so that a corresponding transfer function can be defined in the control system. For example, if a shift of the focus, for example along the horizontal axis, is then desired, the control system must give the command to tilt the laser beam entering the beam-forming arrangement by two axes, for example. In beam-forming arrangements in which multiple laser beams, for example a pre-pulse laser beam and a main pulse laser beam or two pre-pulse laser beams and a main pulse laser beam, are focused on the target material, the same beam path is sometimes provided for different laser beams, i.e., the laser beams are guided to the target material via the same optical elements within the beam-forming arrangement. This is particularly the case if these laser beams have the same wavelength. In this case, an angular offset is provided between the laser beams, which can be, for example, two pre-pulse laser beams of the same wavelength, which leads to a defined local offset between the two laser beams in a focusing plane of the focusing unit of the beam-forming arrangement. This angular offset must also be adjusted by optical elements upstream of the beam-forming arrangement. The orientation of the local offset between the two laser beams in the focusing plane of the focusing unit is therefore also dependent on the image field rotation.

The arrangement and type of optical elements in the beam-forming arrangement differ depending on the type of beam-forming arrangement. Different types of beam-forming arrangements usually differ in terms of the orientation of the laser beam focused by the focusing unit of the beam-forming arrangement in relation to the orientation of the input beam entering into the beam-forming arrangement. Every type of beam-forming arrangement therefore requires a different control system or other optical elements upstream of the beam-forming arrangement in order to be able to focus the laser beam in the same manner. Furthermore, it is more difficult to replace the beam-forming arrangement with another type of beam-forming arrangement with a differing input and output behavior.

### SUMMARY

Embodiments of the present invention provide a device for generating extreme ultraviolet (EUV) radiation. The device includes an optical beam-forming arrangement with a focusing unit for forming a laser beam, and a target material configured to be irradiated with the laser beam to emit EUV radiation. The beam-forming arrangement includes a beam rotator for image field rotation of the laser beam.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 schematically shows a device according to embodiments of the invention and a method according to embodiments of the invention for generating EUV radiation, wherein a laser beam passes through a beam rotator;

FIG. 2 schematically shows the image field rotation achieved by means of the beam rotator, according to some embodiments;

FIG. 3 schematically shows a beam rotator having three mirrors according to some embodiments; and

FIG. 4 schematically shows a beam rotator with five mirrors according to some embodiments.

### DETAILED DESCRIPTION

Embodiments of the invention provide a device in such a way that the same control system of the beam-forming arrangement can be used for different types of beam-forming arrangements and a replacement of the beam-forming arrangement with another type of beam-forming arrangement is facilitated. Embodiments of the invention also provide a method for operating such a device.

Embodiments of the invention provide a device, in which the beam-forming arrangement has a beam rotator for image field rotation of the laser beam.

The beam rotator allows for a simplified control system and a simple replacement of the type of beam-forming arrangement. It is not necessary to intervene in the control system of the beam-forming arrangement, in particular to adjust the transfer function defined in the control system of the beam-forming arrangement, when the beam-forming arrangement is replaced. Furthermore, adjustment of optics upstream of the beam-forming arrangement is avoided.

The beam-forming arrangement preferably has multiple optical elements that can deflect and form the laser beam multiple times.

The beam rotator can be designed to be transmissive and have a Dove prism, for example. However, if a high-power laser beam is used, this can lead to significant heating of the beam rotator and, as a result, damage to the beam rotator. The beam rotator is therefore preferably designed to be reflective and has at least one mirror, in particular multiple mirrors, for guiding the laser beam.

The beam rotator preferably has an odd number of mirrors for guiding the laser beam.

Preferably, the beam rotator has three mirrors or five mirrors for guiding the laser beam. When three mirrors are used, the design of the beam rotator is simplified in terms of construction, whereas when five mirrors are used, flat angles of incidence of the laser beam on the mirrors can be avoided. In this regard, in a base position of the beam rotator, the laser beam is preferably reflected in the beam rotator in such a manner that a laser beam entering the beam rotator is collinear with a laser beam exiting the beam rotator. If the beam rotator is now rotated around a common beam axis of the entering and exiting laser beam by a given angle, the exiting laser beam rotates by twice the angle.

The constructive design and control system of the beam-forming arrangement are further simplified if the beam rotator is arranged in a section of the beam path of the beam-forming arrangement in which the laser beam is collimated.

The beam-forming arrangement can be designed to guide one laser beam and/or multiple laser beams. In particular, the beam-forming arrangement can be designed to guide one or more pre-pulse laser beams and a main pulse laser beam so that the target material is irradiated successively by one or more pre-pulses before being irradiated by a main pulse. If two or more laser beams of the same or similar wavelength, for example two pre-pulse laser beams of the same or similar wavelength, are directed at the target material, these laser beams pass through the same optical elements within the beam-forming arrangement. A defined local offset in the focusing plane of the focusing unit of the beam-forming arrangement is required between these laser beams in order to irradiate the target material at the intended position in each case. This local offset results from an angular offset between the laser beams, which is set in the optical elements upstream of the beam-forming arrangement. The orientation of the local offset between the laser beams depends on the image field rotation in the beam-forming arrangement. Beam-forming arrangements in which two or more laser beams are guided to the target material via the same optical elements and which have a beam rotator that is suitable for adjusting the orientation of the laser beams to one another in a defined manner are therefore advantageous, as the same control system can be used for different types of such beam-forming arrangements.

In this regard, the beam-forming arrangement can have a beam combiner arranged upstream of the beam rotator. The beam combiner upstream of the beam rotator can also be arranged upstream of the beam-forming arrangement. Laser beams of similar or identical wavelengths can be combined at this beam combiner and guided to the target material via the same optical elements. This significantly simplifies the constructive design of the device.

The beam combiner can be designed as a dichroic mirror.

In a preferred embodiment of the invention, the device has a vacuum chamber in which the target material can be irradiated. It is further preferred in this regard that the optical elements of the focusing unit are arranged inside of the vacuum chamber and the beam rotator is arranged outside of the vacuum chamber in order to optimally utilize the installation space available in the vacuum chamber.

Embodiments of the invention also provide a method for generating EUV radiation using a device as described herein. In this regard, the method at least comprises guiding the at least one laser beam through the beam-forming arrangement, in particular through the beam rotator and the focusing unit, as well as irradiating the target material and generating EUV radiation.

The features and advantages described with respect to the device also apply to the method and vice versa.

The at least one laser beam used is preferably pulsed. This is advantageous if the target material is provided as droplets, for example as tin droplets. In this case, the frequency at which the laser beam impacts the droplet corresponds to the frequency at which droplets are emitted from a droplet source.

The focal position of the at least one laser beam used on the target material in the beam direction is preferably adjusted by adjusting the divergence of the laser beam outside of the beam-forming arrangement. This further simplifies the control system of the beam-forming arrangement.

Multiple laser beams can be guided through the beam-forming arrangement for irradiating the target material. The target material can be irradiated successively with one or more pre-pulse laser beams and then with a main pulse laser beam. In this regard, the focal position of the pre-pulse laser beam(s) can be adjusted outside of the beam-forming arrangement and the focal position of the main pulse laser beam can be adjusted inside of the beam-forming arrangement. The focal position of the main pulse laser beam can, in this regard, be adjusted using an actuated mirror.

Further advantages of the embodiments of the invention arise from the description and the drawings. Similarly, the features mentioned above and the features still to be explained may each be used on their own or together in any desired combinations according to embodiments of the invention. The embodiments shown and described should not be understood as an exhaustive list, but rather are of an exemplary character.

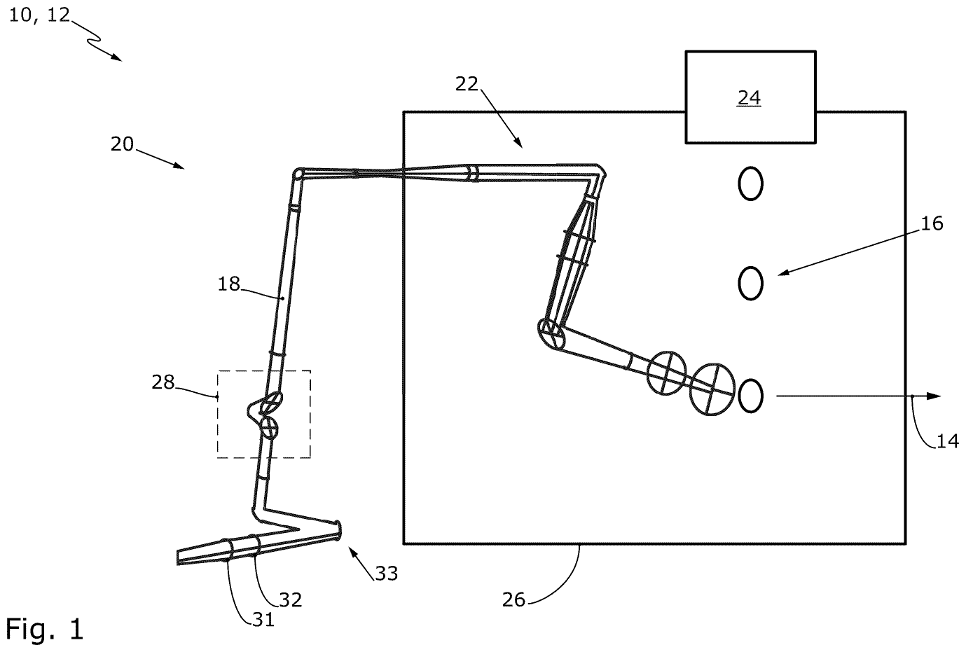

FIG. 1 shows a device 10 and a method 12 for generating EUV radiation 14 on a target material 16 (shown here in the form of multiple droplets, in particular in the form of tin droplets). In this regard, the target material 16 is irradiated by at least one laser beam 18, which passes through a beam-forming arrangement 20 with a focusing unit 22. The focusing unit 22 has multiple optical elements arranged in a vacuum chamber 26. The target material 16, which is dispensed by a target material dispenser 24, and the optical elements of the focusing unit 22 are preferably located in the vacuum chamber 26 of the device 10.

The lateral (X/Y) focal position of the laser beam 18 is adjusted outside of the beam-forming arrangement 20 by tilting and/or shifting the laser beam 18 entering the beam-forming arrangement 20; the focal position of the laser beam 18 in the beam direction (Z) is also controlled outside of the beam-forming arrangement 20 by adjusting the divergence of the laser beam 18 entering the beam-forming arrangement 20. The beam-forming arrangement 20 has multiple optical elements which lead to an image field rotation of the laser beam 18. For example, a horizontal tilt of the laser beam 18 does not lead to a horizontal shift of the focus, but to a shift along an axis rotated relative to the horizontal. Since the focal position is controlled outside of the beam-forming arrangement 20, the input/output behavior of the beam path inside of the beam-forming arrangement 20 must be well known.

In this regard, the beam-forming arrangement 20 can be designed as a modular assembly that can be easily installed in and removed from the device 10. In the embodiment according to FIG. 1, the beam-forming arrangement 20 comprises the lenses 31 and 32 as downstream optical elements. The input laser beam entering into the beam-forming arrangement 20 is formed by the laser beam 18, which has passed through the two lenses 31, 32 and has not yet passed a first deflecting optical element 33. It is to be understood that a different arrangement of optical elements is also possible.

Different focusing unit types can have different image field rotations. In order to be able to use the same upstream beam-forming and control systems for different types of beam-forming arrangements 20, the image field rotation of the respective type of beam-forming arrangement 20 must be taken into account in the transfer function of the control system, which means that the same control system cannot be used for different types of beam-forming arrangements 20. According to embodiments of the invention, on the other hand, a beam rotator 28 is provided which enables different image field rotations of different types of beam-forming arrangements 20 to be adjusted. This allows the same control system to be used for different types of beam-forming arrangements 20.

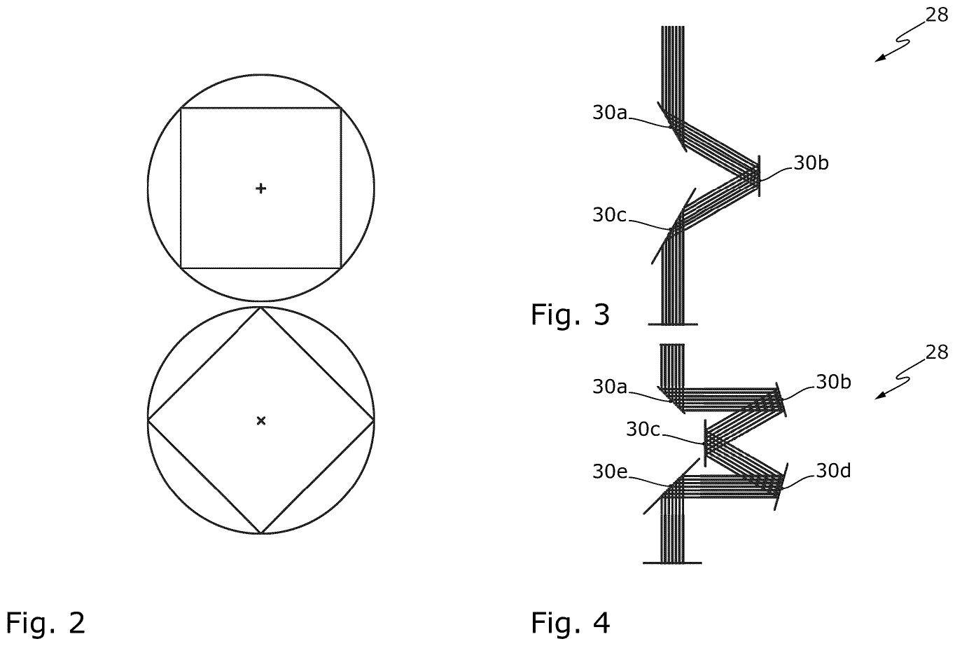

FIG. 2 shows an example of a rotation of the image field plane (lower representation) by 45° when a beam rotator 28 (see FIG. 1) is rotated by 22.5°.

FIG. 3 shows an embodiment of a beam rotator 28 with three mirrors 30a, 30b, 30c.

FIG. 4 shows an alternative embodiment of a beam rotator 28 with five mirrors 30a, 30b, 30c, 30d, 30e, in which flat angles of incidence on the mirrors 30a-30e are avoided.

As described above, embodiments of the invention relate to a device 10 and a method 12 for generating EUV radiation 14 by irradiating target material 16 with at least one laser beam 18. The at least one laser beam 18 is formed by a beam-forming arrangement 20 which has a focusing unit 22. Arranged upstream of the focusing unit 22 is a beam rotator 28 in order for it to be possible to compensate for different image field rotations of different types of beam-forming arrangements 20. As a result, identical optical components can be located upstream of different types of beam-forming arrangements 20, in particular upstream of the beam rotator 28.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SYMBOLS

10 Device
12 Method
14 EUV radiation
16 Target material
18 Laser beam
20 Beam-forming arrangement
22 Focusing unit
24 Target material dispenser
26 Vacuum chamber
28 Beam rotator
30a-e Mirror
31 Lens
32 Lens
33 First deflecting optical element

1. A device for generating extreme ultraviolet (EUV) radiation, the device comprising:
an optical beam-forming arrangement with a focusing unit for forming a laser beam; and
a target material configured to be irradiated with the laser beam to emit EUV radiation;
wherein the beam-forming arrangement comprises a beam rotator for image field rotation of the laser beam.

2. The device according to claim 1, wherein the beam-forming arrangement comprises one or more optical elements configured to deflect the laser beam and/or to form the laser beam multiple times.

3. The device according to claim 1, wherein a beam path of the beam rotator is formed reflectively with multiple mirrors.

4. The device according to claim 3, wherein the beam rotator comprises an odd number of mirrors in the beam path.

5. The device according to claim 4, wherein the beam rotator comprises three mirrors or five mirrors in the beam path.

6. The device according to claim 1, wherein the beam rotator is arranged in a section of a beam path of the beam-forming arrangement in which the laser beam is collimated.

7. The device according to claim 1, wherein the beam-forming arrangement is configured to guide multiple laser beams.

8. The device according to claim 7, further comprising a beam combiner arranged upstream of the beam rotator.

9. The device according to claim 8, wherein the beam combiner is configured as a dichroic mirror.

10. The device according to claim 1, further comprising a vacuum chamber in which the target material is to be irradiated, wherein the focusing unit is arranged inside of the vacuum chamber, and the beam rotator is arranged outside of the vacuum chamber.

11. A method for generating extreme ultraviolet (EUV) radiation with a device according to claim 1, the method comprising:
guiding the laser beam through the beam-forming arrangement, wherein the laser beam passes through the beam rotator and the focusing unit;
irradiating the target material with the laser beam; and
generating EUV radiation.

12. The method according to claim 11, wherein the laser beam is pulsed.

13. The method according to claim 11, wherein a focal position of the laser beam on the target material is adjusted by adjusting a divergence of the laser beam.

14. The method according to claim 11, wherein multiple laser beams are guided through the beam-forming arrangement for irradiating the target material.

15. The method according to claim 14, wherein the multiple laser beams are pulsed.
